(19) United States
(12) Patent Application Publication
(10) Pub. No.: US 2026/0299041 A1
(43) Pub. Date: Oct. 1, 2026

(54) ESTIMATION DEVICE, ESTIMATION METHOD, AND COMPUTER PROGRAM

(71) Applicant: GS Yuasa International Ltd., Kyoto-shi, Kyoto (JP)

(72) Inventor: Katsuya OJI, Kyoto-shi, Kyoto (JP)

(21) Appl. No.: 18/996,245

(22) PCT Filed: Jun. 28, 2023
(86) PCT No.: PCT/JP2023/023991

§ 371 Date: Jan. 17, 2025

(30) Foreign Application Priority Data
Jul. 29, 2022 (JP) 2022-121265

(51) Int. Cl. G01R 31/392; G01R 31/382

(52) U.S. Cl. CPC G01R 31/392; G01R 31/382

(57) ABSTRACT

Page 6 of 47 An estimation device that estimates deterioration of an energy storage device is configured such that, a deterioration value that indicates the deterioration of the energy storage device is not substantially increased during an initial period of an operation of the energy storage device in which characteristics are maintained or enhanced.

### CROSS REFERENCE TO RELATED APPLICATIONS

This application is a National Stage Application, filed under 35 U.S.C. § 371, of International Application No. PCT/JP2023/023991, filed Jun. 28, 2023, which international application claims priority to and the benefit of Japanese Application No. 2022-121265, filed Jul. 29, 2022; the contents of both of which are hereby incorporated by reference in their entirety.

### BACKGROUND

### Technical Field

The present application generally relates to an estimation device, an estimation method, and a computer program for estimating deterioration of an energy storage device.

### Description of Related Art

JP Patent Application No. 2018-060828 discloses a technique where time-series data of a state of charge (SOC) in an energy storage device is acquired, and a deterioration value that indicates the deterioration of the energy storage device is estimated such that the deterioration value is increased in proportion to a magnitude of a fluctuation in the SOC.

### BRIEF SUMMARY

In order to enhance accuracy of deterioration estimation of an energy storage device, there is still a room for improvement.

According to one aspect of the present invention, an estimation device, an estimation method and a computer program that can enhance accuracy of the deterioration estimation of an energy storage device are provided.

According to an aspect of the present invention, an estimation device that estimates the deterioration of an energy storage device is configured such that a deterioration value that indicates the deterioration is not substantially increased during an initial period of an operation of the energy storage device in which characteristics are maintained or enhanced.

According to the above-mentioned aspect of the present invention, the accuracy of the deterioration estimation can be enhanced by taking into account maintenance/enhancement of the characteristics of the energy storage device observed in the initial period of the operation.

### BRIEF DESCRIPTION OF THE FIGURES

FIG. 1 is a view illustrating an overall configuration of a remote monitoring system.

FIG. 2 is a view illustrating one example of a hierarchical structure of a group of energy storage modules and a connection mode of a communication device.

FIG. 3 is a block diagram illustrating the internal configuration of devices included in the remote monitoring system.

FIG. 4 is a schematic view illustrating an operation of a deterioration simulator.

FIG. 5 is a graph illustrating the relationship between the number of cycles and a capacity deterioration rate (deterioration value).

FIG. 6 is a graph illustrating the transition of a capacity deterioration rate in accordance with a magnitude of a fluctuation in an SOC in the energy storage device during an initial period of an operation.

FIG. 7 is a view illustrating a deterioration behavior when the magnitude of the fluctuation in the SOC is changed in the midst of the operation during an initial period.

FIG. 8 is a graph illustrating the transition of a capacity deterioration rate in accordance with a temperature.

FIG. 9 is a view illustrating a method of preventing a substantial increase of a deterioration value during a period in which characteristics of the energy storage device are maintained or enhanced.

FIG. 10 is a flowchart describing other calculation steps of a capacity deterioration rate.

FIG. 11 is a view complementarily describing calculation steps in FIG. 10.

### DETAILED DESCRIPTION OF VARIOUS EMBODIMENTS

Hereinafter, the overall configuration of an embodiment is described.
(1) An estimation device for estimating deterioration of an energy storage device is configured such that during an initial period of an operation of the energy storage device in which characteristics are maintained or enhanced, a deterioration value that indicates the deterioration is not substantially increased.

In the present specification, the “energy storage device” may include a plurality of energy storage cells, a plurality of energy storage modules (energy storage packs), or a plurality of banks (strings). Alternatively, the “energy storage device” may be a single energy storage cell.

The “characteristics” may be a full charge capacity or a high rate characteristic of the energy storage device, but is not limited to such characteristics.

The “deterioration value” is preferably a capacity deterioration rate indicating the degree of decrease of capacity in the full charge capacity as a percentage. Alternatively, the “deterioration value” may be a value that reflects other deterioration factors such as an increase in internal resistance (Ohmic resistance, non-Ohmic resistance).

The expression “the deterioration value of the energy storage device is not substantially increased” may means that (a) the deterioration value is maintained at a value near zero during a period in which the characteristics of the energy storage device are maintained or enhanced, or (b) the deterioration value is not increased as a positive value by gradually increasing the deterioration value set as a negative initial value.

The present inventor has focused on the fact that in an energy storage cell such as a lithium ion battery, the maintenance/enhancement of characteristics such as an increase in full charge capacity is observed at an initial period of an operation (an initial period of a charge-discharge cycle), and has arrived at the above-mentioned configuration. It is estimated that the increase of a full charge capacity is brought about by the following reasons. One reason is that an electrolytic solution permeates into a positive electrode plate, into a negative electrode plate, into a separator, or between the positive electrode plate or the negative electrode plate and the separator. Another reason is that cracks are generated in secondary particles of a positive active material due to charging and discharging (expansion and contraction of a positive active material) of an energy storage cell so that a surface area of the positive active material contributing to a charging and discharging reaction increases, whereby a high rate characteristic is enhanced.

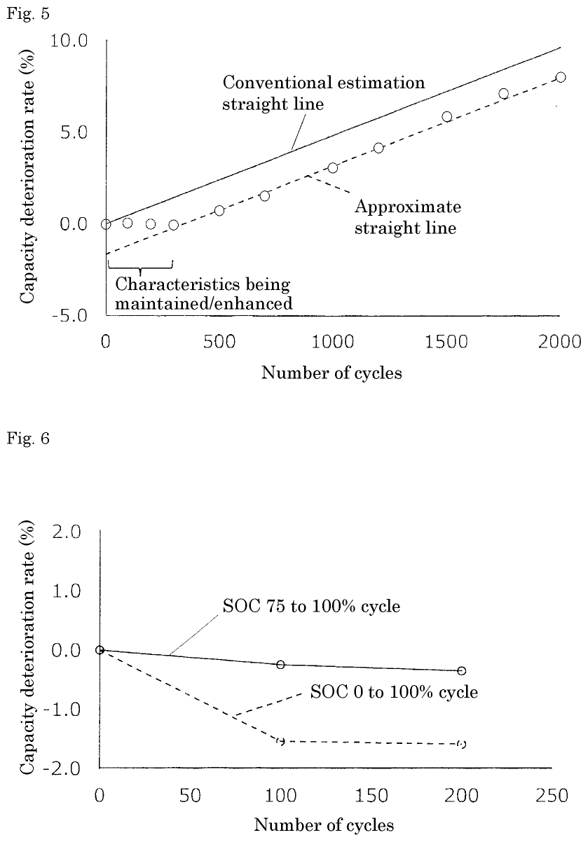

As illustrated in FIG. 5, there is a case where a conventional estimated straight line indicated by a solid line in FIG. 5 that simulates a deterioration value that starts its increase from an initial period of a cycle, sometimes deviates from an actual deterioration behavior of an energy storage cell indicated by a broken line (an approximate straight line obtained by fitting actual measured values indicated by round dots). This is because the conventional estimated straight line does not take into account the maintenance/enhancement of the characteristics of the energy storage device observed during an initial period of the operation.

As the case of the approximate straight line indicated by a broken line in FIG. 5, by not substantially increasing the deterioration value during the initial period of the operation (for example, up to about 200 to 350 cycles) by taking into account the maintenance/enhancement of the characteristics of the energy storage device during such an operation period, the accuracy of the deterioration estimation can be enhanced.

In FIG. 5, an axis of abscissas indicates the number of times (the number of cycles) that charging and discharging are repeated in an SOC range of zero to 100%. The term “cycle” used in the present specification is not limited to the above-mentioned example, and may be a partial repetition of charging and discharging in the SOC range of zero to 100%.
(2) The estimation device according to the above-mentioned (1) may make a determination relating to an increase in the deterioration value based on a magnitude of a fluctuation in a state of charge (SOC) during the initial period of the operation of the energy storage device.

The present inventor has found that different deterioration behaviors appear in accordance with the magnitude of the fluctuation in the SOC during an initial period of an operation of the energy storage device, and has arrived at the above-mentioned configuration. With such a configuration, it is possible to enhance accuracy of the estimation of deterioration of the energy storage device.
(3) In the estimation device according to the above-mentioned (2), it may be configured such that as the magnitude of the fluctuation in the SOC is larger, a full charge capacity of the energy storage device during the initial period of the operation is more largely increased, and the deterioration value of the energy storage device having the increased full charge capacity is increased.

As illustrated in FIG. 6, in the energy storage device during an initial period of an operation, there may be a case where a capacity deterioration rate takes a negative value (that is, a full charge capacity is increased) along with an increase in the number of cycles. In FIG. 6, the solid line indicates the transition of a capacity deterioration rate when the energy storage device is charged and discharged with an SOC of 75 to 100%, and the broken line indicates the transition of the capacity deterioration rate when the energy storage device is charged and discharged with an SOC of zero to 100%. The tendency is observed that the larger the magnitude of the fluctuation in the SOC, the larger a negative value of the capacity deterioration rate of the energy storage device takes (that is, the full charge capacity is increased) during an initial period of the operation. Accordingly, the accuracy of the deterioration estimation of the energy storage device can be enhanced by taking into account (reflecting it to the estimation) this tendency.
(4) In the estimation device according to (2) or (3), when the SOC of the energy storage device fluctuates up to a predetermined number of cycles with a first magnitude (amplitude), and then the SOC of the energy storage device fluctuates with a second magnitude that is larger than the first magnitude, a full charge capacity of the energy storage device during the initial period of the operation may be increased based on the second magnitude, and the deterioration value of the energy storage device having the increased full charge capacity may be increased.

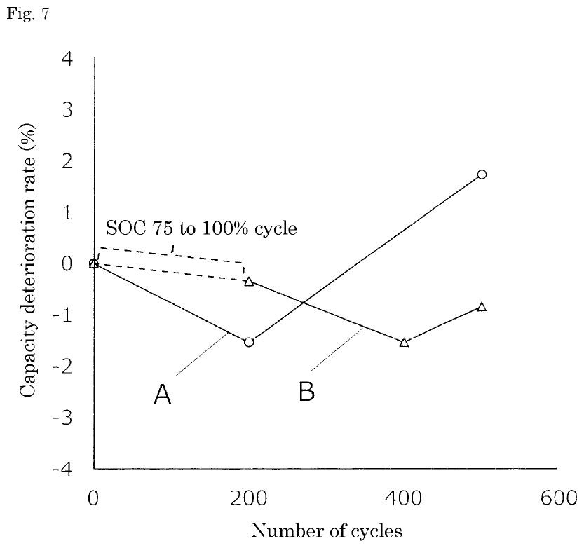

A polygonal line A in FIG. 7 indicates a transition of a capacity deterioration rate when the energy storage device is charged and discharged with an SOC of zero to 100% from the start of the operation. A polygonal line B in FIG. 7 indicates the transition of a capacity deterioration rate when the energy storage device is charged and discharged with an SOC of 75 to 100% up to a predetermined number of cycles as indicated by a broken line, and thereafter, the energy storage device is charged and discharged with the SOC of zero to 100% as indicated by a solid line. In both the case where the SOC of the energy storage device fluctuates with the second magnitude from the initial period of a cycle as indicated by the polygonal line A and the case where the SOC of the energy storage device fluctuates from the first magnitude to the second magnitude in the midst of the cycle as indicated by the polygonal line B, there is a tendency that a full charge capacity of the energy storage device is increased to the same level. By taking into account this tendency (by reflecting the tendency in the estimation), when the magnitude of the fluctuation in the SOC is changed in the midst of the cycle during the initial period of the operation, accuracy of deterioration estimation of the energy storage device can be enhanced.
(5) The estimation device according to any one of the above-mentioned (1) to (4) may make a determination relating to an increase in the deterioration value based on a temperature during the initial period of the operation of the energy storage device.

In the present specification, the term “temperature” may indicate a surface temperature of the energy storage device measured by a sensor, or may indicate an environmental temperature of the energy storage device measured by a thermometer. Alternatively, the term “temperature” may indicate an internal temperature of the energy storage device estimated by simulation.

The present inventor has found that different deterioration behaviors appear in accordance with a temperature of the energy storage device at the time of initial period of the operation of the energy storage device, and has arrived at the above-mentioned configuration.

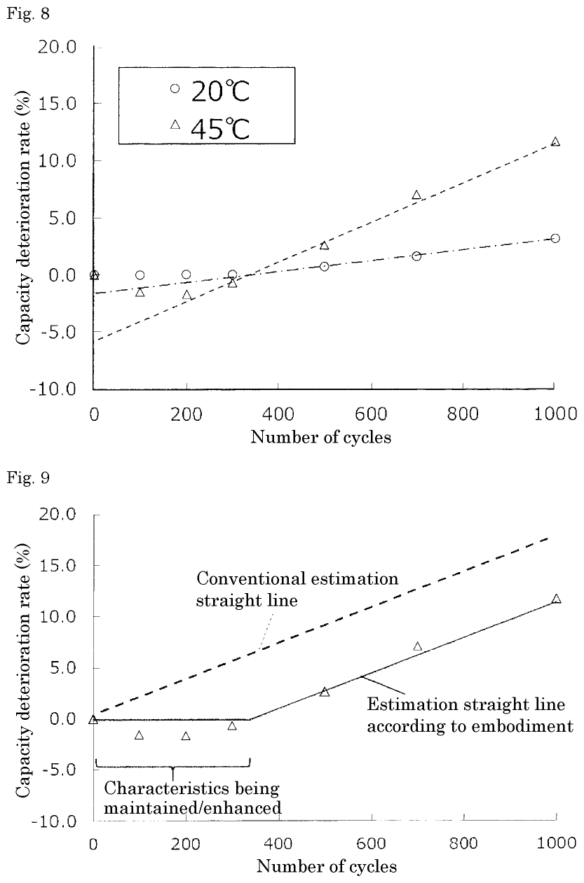

The deterioration behavior (an approximate straight line that is indicated by a broken line in FIG. 8 and is obtained by fitting actually measured values indicated by a triangular dot) of an energy storage cell when a temperature is 45° C. has the larger in gradient than the deterioration behavior (an approximate straight line obtained by fitting actually measured values indicated by a round dot) of the energy cell when the temperature is 20° C. indicated by a chained line. There is a tendency where, compared to a case where the temperature is 20° C., in the case where the temperature is 45° C., a capacity deterioration rate of the energy storage device during the initial period of the operation takes a larger negative value (that is, a full charge capacity is increased more). Accordingly, the accuracy of the deterioration estimation of the energy storage device can be enhanced by taking into account (reflecting) this tendency.
(6) In an estimation method of estimating deterioration of an energy storage device, a deterioration value that indicates the deterioration is not substantially increased during an initial period of an operation of the energy storage device in which characteristics are maintained or enhanced.
(7) A computer program allows a computer that estimates deterioration of an energy storage device to perform processing of not substantially increasing a deterioration value that indicates the deterioration during an initial period of an operation of the energy storage device in which characteristics are maintained or enhanced.

The above-mentioned estimation method and the computer program may be performed using a computer positioned closed to the energy storage device. Alternatively, the above-mentioned estimation method and the computer program may be performed by a computer positioned away from the energy storage device (for example, an electronic control unit (ECU) of a mobile body such as a vehicle on which the energy storage device is mounted, a remote monitoring server or the like).

A method substantially equal to the configurations described in the above-mentioned (2) to (5) may be applied to the above-mentioned estimation method and the computer program.

Hereinafter, an embodiment is specifically described with reference to drawings.

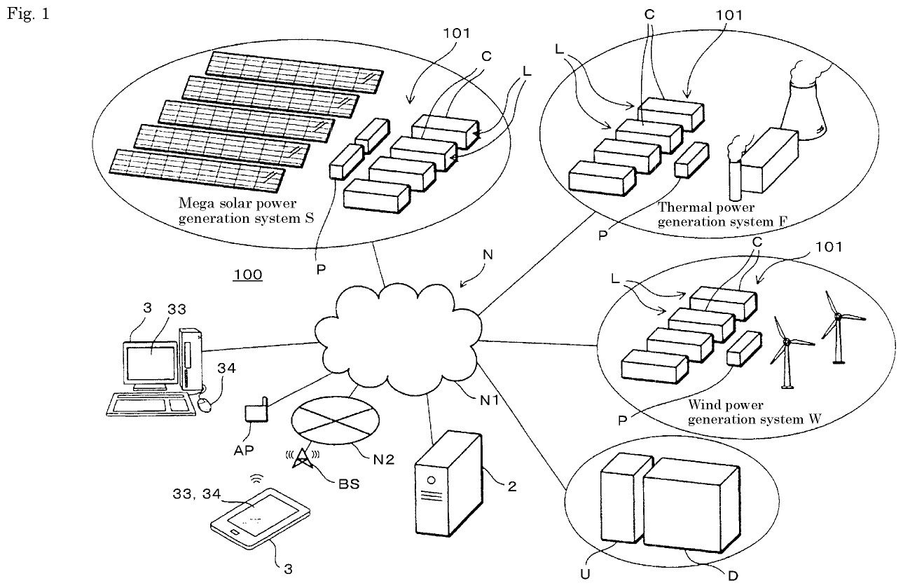

FIG. 1 is a view illustrating an overall configuration of a remote monitoring system 100. A mega solar power generating system S, a thermal power generating system F, a wind power generating system W, and other distributed power sources respectively include an energy storage device and a power source associated device. The remote monitoring system 100 can get access to information relating to the energy storage device and the power source associated device from a remote place. An uninterruptible power source (UPS) U provided in a data center or the like, a rectifier (DC power source) provided in a railway stabilization power source system or the like, or a converter D may be remotely monitored. The energy storage device is built in or is connected to the uninterruptible power source U, the DC power source device, or the converter D.

An energy storage system 101 is disposed together with a power conditioner (power conditioning system (PCS)) P in the mega solar power generating system S, the thermal power generating system F, and the wind power generating system W. The energy storage system 101 may be configured by a plurality of containers C in each of which a group of energy storage modules L is housed. Alternatively, the group of energy storage modules L and the power conditioning system P may be disposed in a building (an energy storage room). The group of energy storage modules L each include a plurality of secondary batteries such as lithium ion batteries.

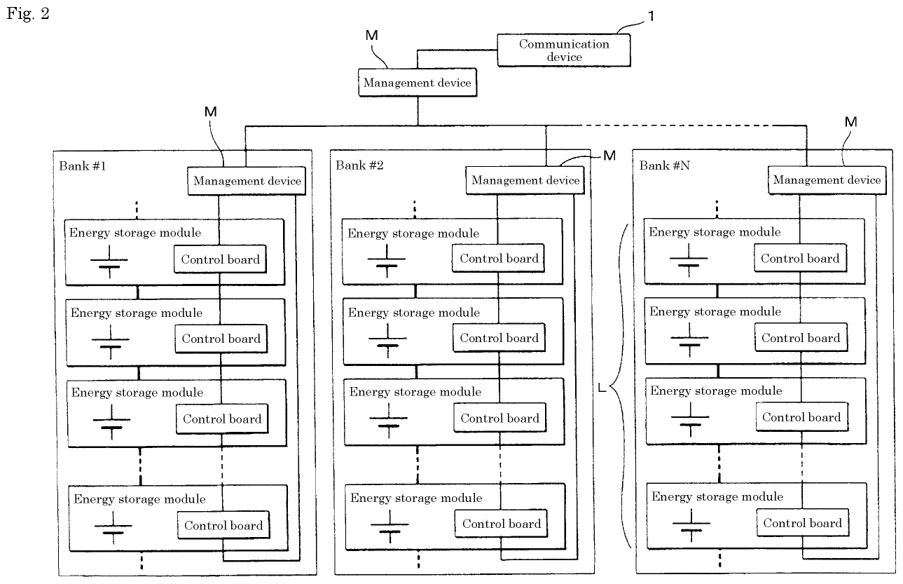

In the remote monitoring system 100, the communication device 1 (see FIG. 2) is mounted on/connected to each of the energy storage systems 101 or apparatuses (P, U, D and a management device M to be described later) in the systems S, F, and W that are monitoring targets. The remote monitoring system 100 includes: the communication device 1; a server device 2 (information processing device) that collects information from the communication device 1; a client device 3 (terminal apparatus) that browses the collected information; and a network N that is a communication medium between the apparatuses.

The communication device 1 may be a measurement monitor that communicates with a battery management unit (BMU) included in the energy storage device to receive information on the energy storage device, or may be a controller compatible with an ECHONET/ECHONETLite (registered trademark). The communication device 1 may be an independent device or a network card type device that can be mounted on the power conditioner P or the group of energy storage modules L. One communication device 1 is provided to each group that includes a plurality of energy storage modules in order to acquire information on the group of energy storage modules L in the energy storage system 101.

The server device 2 includes a web server function, and offers information obtained from the communication device 1 that is mounted on or is connected to each apparatus that is a monitoring target, in response to an access from the client device 3.

The network N includes: a public communication network N1 that is a so-called Internet; and a carrier network N2 that realizes wireless communication in accordance with a predetermined mobile communication standard. The public communication network N1 includes a general optical line, and the network N includes a dedicated line connected to the server device 2. The carrier network N2 includes a base station BS, and the client device 3 can communicate with the server device 2 from the base station BS via the network N. An access point AP is connected to the public communication network N1, and the transmission and reception of information can be performed between the client device 3 and the server device 2 from the access point AP via the network N.

The group of energy storage modules L of the energy storage system 101 has a hierarchical structure. FIG. 2 is a view illustrating one example of the hierarchical structure of the group of energy storage modules L and a connection mode of the communication device 1. The group of energy storage modules L has, for example, a hierarchical structure where the energy storage module is configured by connecting a plurality of energy storage cells in series; and a bank is formed by connecting a plurality of energy storage modules in series. In the example illustrated in FIG. 2, one management device M is provided to each of the banks numbered (#) 1 to N, and a group of banks (also referred to as domains) in which the banks are connected in parallel. The management device M that is provided to each bank communicates with a control board (cell management units (CMU)) equipped with a communication function that is built in each energy storage module by serial communication, and acquires measurement data (currents, voltages, and temperatures) of the energy storage cells in each energy storage module. With respect to the respective management devices M of the banks 1, measurement data obtained from the energy storage modules of each bank is transmitted to the management device M provided in a domain. The management device M provided in the domain collects information such as measurement data obtained from the management devices M of the banks belonging to the domain, and detected abnormality.

Although not illustrated in detail, the energy storage cell may include: a hollow rectangular parallelepiped case; and a pair of cell terminals having different polarities and provided on one side surface (terminal surface, upper surface) of the case. In the case, an electrode assembly formed by stacking a positive electrode, a separator and a negative electrode, and an electrolyte (electrolytic solution) are accommodated.

Alternatively, the electrode assembly may be formed by making a positive electrode having a sheet shape, a negative electrode having a sheet shape overlap with each other by way of two separators each having a sheet shape, and by winding these components (vertical winding or lateral winding). The separator is formed of a porous resin film. As the porous resin film, a porous resin film made of a resin such as polyethylene (PE) or polypropylene (PP) can be used.

The positive electrode is an electrode plate where a positive active material layer is formed on a surface of a positive electrode substrate having an elongated strip shape that is made of aluminum, an aluminum alloy or the like, for example. The positive active material layer contains a positive active material. As the positive active material used in the positive active material layer, a material that can occlude and release lithium ions can be used. As the positive active material, LiFePO₄ is used, for example. However, the positive active material is not limited to such a material, and a so-called ternary positive active material may be used. The positive active material layer may further contain a conduction promoting agent, a binder, and the like.

The negative electrode is an electrode plate where a negative active material layer is formed on a surface of a negative electrode substrate having an elongated strip shape that is made of copper, a copper alloy or the like, for example. The negative active material layer contains a negative active material. As the negative active material, a material that can occlude and release lithium ions can be used. Examples of the negative active material include graphite, hard carbon, and soft carbon. The negative active material layer may further contain a binder, a thickener and the like.

As an electrolyte accommodated in the case together with an electrode assembly, an electrolyte substantially equal to an electrolyte used in a conventional lithium ion secondary battery can be used. For example, as the electrolyte, an electrolyte that contains a support salt in an organic solvent can be used. As the organic solvent, for example, a non-proton solvent such as a carbonate group, an ester group, an ether group or the like can be used. As the support salt, for example, a lithium salt such as LiPF₆, LiBF₄, and LiClO₄ can be preferably used. The electrolyte may contain, for example, various additives such as a gas generating agent, a film forming agent, a dispersion agent, and a thickener.

The energy storage cell is not limited to a prismatic (prismatic) cell, and may be a cylindrical lithium ion battery or a laminate type (pouch type) lithium ion battery. The energy storage cell may be a lithium ion battery that includes a stacked electrode assembly in place of a wound electrode assembly. The energy storage cell may be an all-solid-state lithium ion battery that uses a solid electrolyte.

In the remote monitoring system 100, the server device 2 collects, by using the communication device 1 mounted on each apparatus, information such as states of SOCs or states of health (SOHs), or a detected abnormality in the energy storage cells, the energy storage modules, or the banks of the energy storage system 101, and presents a state of the energy storage system 101 based on the collected data.

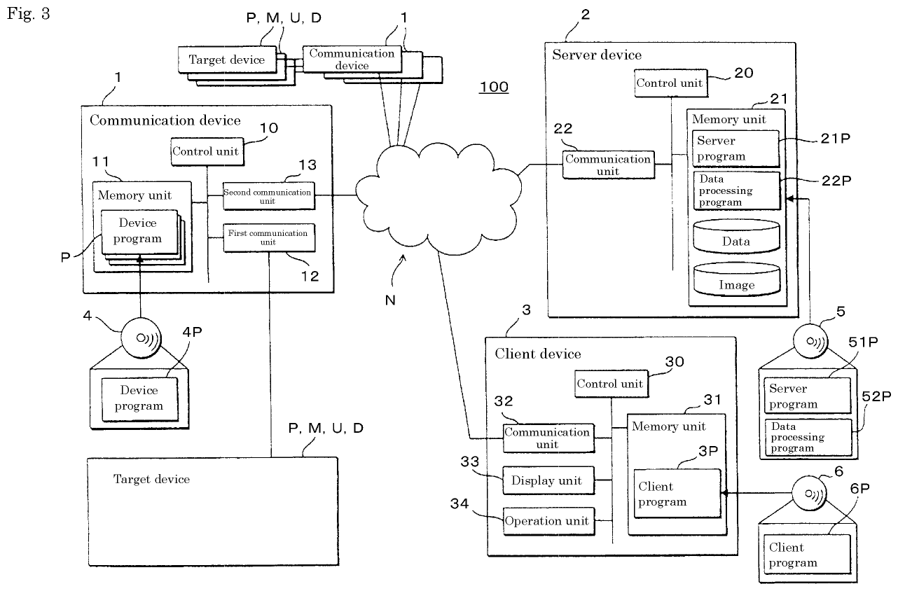

FIG. 3 is a block diagram illustrating an internal configuration of apparatuses included in the remote monitoring system 100. As illustrated in FIG. 3, the communication device 1 includes a control unit 10, a memory unit 11, a first communication unit 12, and a second communication unit 13. The control unit 10 is a processor that uses a central processing unit (CPU), and performs processing by controlling the respective constitutional units using a built-in memory such as a read only memory (ROM) and a random access memory (RAM).

The memory unit 11 is formed of a nonvolatile memory such as a flash memory. The memory unit 11 stores a device program 1P that the control unit 10 reads and performs. The device program 1P includes a communication program conforming to Secure Shell (SSH), Simple Network Management Protocol (SNMP), or the like. The memory unit 11 stores information such as information collected by the processing of the control unit 10 and an event log. The information stored in the memory unit 11 can also be read out via a communication interface such as a USB whose terminal is exposed to a housing of the communication device 1. A device program 1P stored in the memory unit 11 may be obtained by reading out a device program 4P that is stored in the recording medium 4 and by copying the device program 4P to the memory unit 11.

The first communication unit 12 is a communication interface that realizes communication between the communication device 1 and a monitoring target device to which the communication device 1 is connected. As the first communication unit 12, a serial communication interface such as an RS-232C or an RS-485 is used, for example. For example, the power conditioner P includes a control unit having a serial communication function conforming to the RS-485, and the first communication unit 12 communicates with the control unit. In a case where control boards that are included in the group of energy storage modules L are connected by a controller area network (CAN) bus so that the communication between the control boards can be realized by CAN communication, the first communication unit 12 forms a communication interface based on a CAN protocol. The first communication unit 12 may be a communication interface compatible with an ECHONET/ECHONETLite standard.

The second communication unit 13 is an interface that realizes communication via the network N. As the second communication unit 13, a communication interface such as Ethernet (registered trademark) or a wireless communication antenna is used, for example. The control unit 10 is communicably connectable to the server device 2 via the second communication unit 13. The second communication unit 13 may be a communication interface conforming to an ECHONET/ECHONETLite standard.

In the communication device 1 having such a configuration, the control unit 10 acquires measurement data relating to the energy storage device obtained in the apparatus to which the communication device 1 is connected via the first communication unit 12. The control unit 10 may function as an SNMP agent by reading and executing an SNMP program and respond to an information request from the server device 2.

As the server device 2, a server computer is used. The server device 2 includes a control unit 20, a memory unit 21, and a communication unit 22. In the present embodiment, the server device 2 is described as one server computer. However, processing may be performed in a distributed manner using a plurality of server computers.

In the present embodiment, the server device 2 functions as a deterioration simulator (estimation device) 2a described later.

The control unit 20 is a processor that uses a CPU or a graphics processing unit (GPU), and performs processing by controlling the respective constitutional units using a built-in memory such as a ROM and a RAM. The control unit 20 performs communication and information processing based on a server program 21P stored in the memory unit 21. The server program 21P includes a web server program, and the control unit 20 functions as a web server that performs providing of a web page to the client device 3. The control unit 20 collects, as an SNMP server, information from the communication device 1 in accordance with the server program 21P.

As the memory unit 21, for example, a non-volatile memory such as a hard disc or a flash memory is used. The memory unit 21 has stored the server program 21P described above and a data processing program 22P. The server program 21P and the data processing program 22P stored in the memory unit 21 may be programs that are obtained by reading a server program 51P and a data processing program 52P that are stored in the recording medium 5 and by copying them to the memory unit 21.

The memory unit 21 stores measurement data of the power conditioner P and the group of energy storage modules L of the energy storage system 101 that is a monitoring target collected by processing performed by the control unit 20. The measurement data is associated with identification information (number) for identifying the energy storage system 101 or the power conditioner P. The measurement data of the group of energy storage modules L is stored in accordance with a domain, a bank, a module, or a cell and a hierarchical structure.

The communication unit 22 is a communication device that realizes the communication connection and the transmission and reception of information via the network N. Specifically, the communication unit 22 is a network card compatible with the network N.

The client device 3 is a computer used by an operator such as an administrator or a person in charge of maintenance of the energy storage system 101 of the power generating systems S, F, and W. The client device 3 may be a personal computer of a desktop type or a laptop type, or may be a so-called smartphone or a communication terminal of a tablet type. The client device 3 includes a control unit 30, a memory unit 31, a communication unit 32, a display unit 33, and an operation unit 34.

The control unit 30 is a processor that uses a CPU. The control unit 30 allows the display unit 33 to display a web page provided by the server device 2 based on a client program 3P stored in the memory unit 31. The client program 3P is a program that is incorporated in a web page provided by a web server function of the server device 2. The client program 3P includes a script and a web browser program that are temporarily stored in the client device 3. The client program 3P is a program for displaying a web-based screen based on an operation in the server device 2.

As the memory unit 31, for example, a non-volatile memory such as a hard disk or a flash memory is used. The memory unit 31 has stored various programs including a client program 3P. The client program 3P may be a program obtained by reading a client program 6P stored in the recording medium 6 and by copying the client program 6P to the memory unit 11.

As the communication unit 32, a communication device such as a network card for wired communication, a wireless communication device for mobile communication connected to the base station BS (see FIG. 1), or a wireless communication device compatible with connection to an access point AP is used. The control unit 30 can perform the communication connection or the transmission and reception of information between the control unit 30 and the server device 2 via the network N by the communication unit 32.

As the display unit 33, a display such as a liquid crystal display or an organic electro luminescence (EL) display is used. The display unit 33 displays an image on a web page provided by the server device 2 in accordance with processing performed based on the client program 3P of the control unit 30. The display unit 33 is preferably a touch panel built-in display. However, the display unit 33 may be a touch panel non-built-in display.

The operation unit 34 is a user interface such as a keyboard, a pointing device or a voice inputting unit capable of performing inputting and outputting of data and commands between the operation unit 34 and the control unit 30. The operation unit 34 may use a touch panel of the display unit 33 or a physical button mounted on a housing. The operation unit 34 notifies the control unit 30 of operation information produced by a user.

In the remote monitoring system 100 having the configuration described above, the server device 2 periodically acquires various pieces of information including states of the power conditioner P, the group of energy storage modules L (management device M), the uninterruptible power source U, and the rectifier D from the communication device 1 based on the data processing program 22P, and stores these information in the memory unit 21. The communication device 1 transmits state information relating to the group of energy storage modules L that are associated with the master-slave relationship in accordance with the hierarchical structure. The server device 2 prepares, based on information acquired from the energy storage devices or the respective power-supply related apparatuses using the communication device 1, screen information that visually displays the state of the system or the apparatus that is a monitoring target in accordance with the hierarchical structure of the group of energy storage modules, and transmits and offers the screen information to the client device 3.

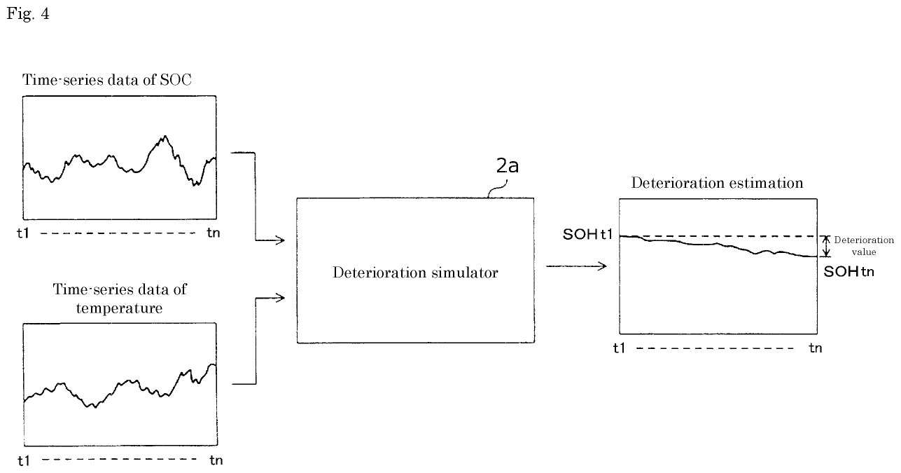

FIG. 4 is a schematic diagram illustrating the operation of a deterioration simulator 2a. When the deterioration simulator 2a acquires the time-series data of the SOC and the time-series data of the temperature as input data, the deterioration simulator 2a estimates (calculates) the deterioration value of the energy storage device. As illustrated in FIG. 4, the time-series data of the SOC indicates the fluctuation in the SOC from a point of time t1 to a point of time tn (for example, the fluctuation in n pieces of SOCs values at respective points of time), and the time-series data of the temperature indicates the fluctuation in the temperature from the point of time t1 to the point of time tn (for example, the fluctuation in n pieces of temperature values for the respective point of time).

The deterioration simulator 2a can estimate a decrease (deterioration value) of the SOH of the energy storage device from the point of time t1 to the point of time tn based on the fluctuations in the SOC and the temperature from the point of time t1 to the point of time tn.

Assuming the SOH at the point of time t1 is as SOHt1 and the SOH at the time point tn as SOHtn, the deterioration value becomes (SOHt−SOHtn). That is, when the SOH at the point of time t1 is known, the SOH at the point of time tn can be obtained based on the deterioration value. In the above-mentioned processing, the point of time t1 may be set as a certain point of time in the past, in the present, or in the future, and the point of time tn may be set as a point of time when a predetermined time has elapsed from the point of time t1 toward the future. The time difference between the point of time t1 and the point of time tn is a deterioration prediction target period of the deterioration simulator 2a, and can be appropriately set in accordance with how long the deterioration value is predicted in the future. The time difference between the point of time t1 and the point of time tn can be set to, for example, one month, half a year, one year, or two years.

In the example illustrated in FIG. 4, the time series data of a temperature is inputted to the deterioration simulator 2a. However, a representative temperature (for example, an average temperature from the point of time t1 to the point of time tn) may be inputted to the deterioration simulator 2a in place of the time series data of the temperature.

The deterioration simulator 2a in the present embodiment does not substantially increase a deterioration value (in the present embodiment, a deterioration rate of a full charge capacity) indicating the deterioration during a period in which the characteristics are maintained or enhanced during an initial period of the operation of the energy storage device. An example of a specific method of preventing such an increase of the deterioration value will be described with reference to FIG. 9.

FIG. 9 shows a method of maintaining the deterioration value at zero (the capacity deterioration rate is not increased along with an increase in the number of cycles) during a period in which the characteristics of the energy storage device are maintained/enhanced.

The deterioration simulator 2a estimates how much the characteristics of the energy storage device are maintained/enhanced based on the magnitude of the fluctuation in the SOC and the temperature at an initial period of the operation of the energy storage device, and determines the number of cycles from which the capacity deterioration rate is increased as a positive value. In an estimated straight line illustrated in FIG. 9, the capacity deterioration rate increases as a positive value from around 350 cycles. The capacity deterioration rate is maintained at zero until the number of cycle becomes 350 cycles. In other words, the cycle deterioration value is maintained at zero during a period in which the full charge capacity of the energy storage device increases.

A conventional estimated straight line indicated by a broken line illustrated in FIG. 9 simulates a deterioration value starting from the initial period of the cycle. The conventional estimated straight line deviates from measured values indicated by triangular points. This is because the maintenance/enhancement of the characteristics of the energy storage device observed at the initial period of the operation is not taken into account. On the other hand, the estimated straight line according to the present embodiment that is indicated by a solid line illustrated in FIG. 9 maintains a capacity deterioration rate at zero at an initial period of the cycle, and thereafter, increases the capacity deterioration rate so as to follow an approximate straight line obtained by fitting actually measured values. As described above, the accuracy of the deterioration estimation can be enhanced by taking into account the maintenance/enhancement of the characteristics of the energy storage device during an initial period of the operation in such a manner that the deterioration value is not substantially increased during such an operation period. With the enhancement of the accuracy of the deterioration estimation, it is possible to reduce the occurrence of a phenomenon such as a failure of the energy storage system or non-satisfying of a request, and to perform appropriate preventive maintenance. It is preferable to intensively perform such an estimation method using the server device 2 in the remote monitoring system 100 that monitors the plurality of energy storage systems and the apparatuses illustrated in FIG. 1. With such a method, it is possible to determine priorities and to perform appropriate preventive maintenance with limited resources while suppressing an increase in cost.

This technique is useful not only after the operation of the power storage system is started but also at the time of designing and proposing the energy storage system. As indicated by the broken line illustrated in FIG. 9, when the deterioration of the energy storage device is excessively largely estimated by a conventional method, it is necessary to use the energy storage cells or the energy storage modules more than necessary in order to satisfy a demand (for example, a demand for maintaining a predetermined storage capacity (dischargeable electric quantity) for 10 years or more) with respect to the energy storage system. Accordingly, the cost of the energy storage system increases and hence, the energy storage system loses a cost competitiveness. On the other hand, when the method of the present embodiment indicated by the solid line illustrated in FIG. 9 is applied, the future deterioration of the energy storage device can be estimated with high accuracy. Accordingly, the energy storage system having high cost competitiveness can be constructed using the energy storage cells and the energy storage module necessary and sufficient to satisfy the demand.

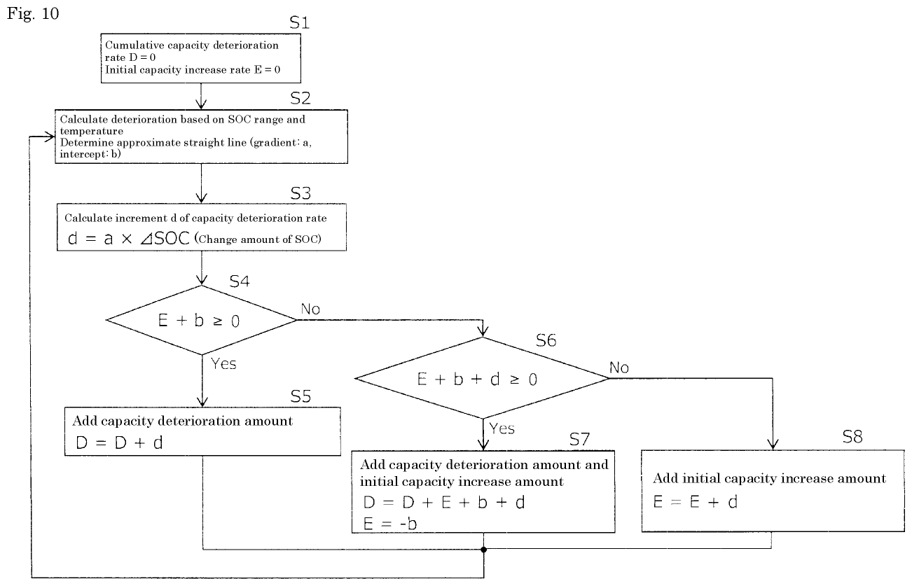

The method illustrated in FIG. 9 is suitably used when the operation environment is constant (a magnitude in the fluctuation in the SOC being constant and a temperature being constant). On the other hand, a method illustrated in FIG. 10 can be suitably used in a case where a range of the SOC or a range of the temperature changes during an operation of the energy storage device. The processing illustrated in FIG. 10 may be performed at a preset time interval after the operation of the energy storage device is started.

At the time of starting the operation of the energy storage device, in step S1 illustrated in FIG. 10, a cumulative capacity deterioration rate (hereinafter, simply referred to as a “capacity deterioration rate”) D of the energy storage device is set to zero. A full charge capacity increase rate (hereinafter, simply referred to as “initial capacity increase rate”) E at an initial period of the operation of the energy storage device is set to zero.

Next, in step S2, an approximate straight line (a gradient: a, intercept: b) for estimating the deterioration is determined based on a charging-discharging SOC range (any range of the SOC of zero to 100, and the magnitude of the fluctuation) and the temperature of the energy storage device at the time of the calculation. Data (for example, table data, functions, and the like) for determining the approximate straight lines in accordance with the respective SOC ranges or the respective temperatures may be stored in the memory unit 21 (see FIG. 3) of the server device 2.

The approximate straight line for estimating the deterioration will be described in detail hereinafter. An approximate straight line indicated by the broken line in FIG. 5 is expressed by an expression of y=ax+b. In the expression, y represents a capacity deterioration rate, and x represents the number of cycles. As illustrated in FIG. 8, a gradient a of the approximate straight line changes in accordance with a temperature of the energy storage device. An intercept b of the approximate straight line (capacity deterioration rate being set to a negative value at a point of time where the number of cycles is zero) changes in accordance with a range of the SOC of the energy storage device illustrated in FIG. 6 and a temperature illustrated in FIG. 8.

In step S2, the approximate straight line (gradient a, intercept b) for estimating a deterioration in accordance with the range of the SOC and the temperature of the energy storage device at a point of time of calculation is determined based on data stored in the server device 2.

Next, in step S3, an increment d of the capacity deterioration rate from the previous point of time of calculation is calculated using the gradient a obtained in step S2 and a fluctuation amount ΔSOC of the SOC per unit time. That is, the increment d is calculated with an expression d=a×ΔSOC.

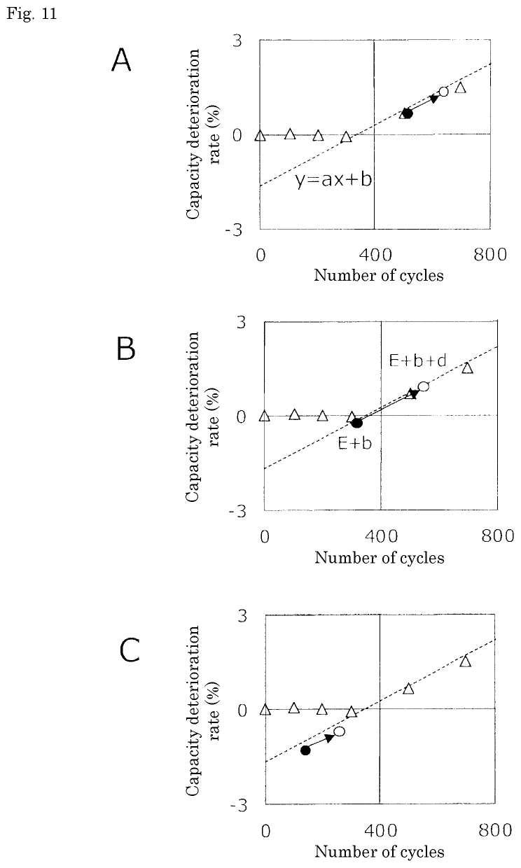

Next, in step S4, it is determined whether or not a value obtained by adding the intercept b to the initial capacity increase rate E is zero or more. When this value is zero or more (S4: Yes), a period during which the characteristics of the energy storage device are maintained or enhanced has already elapsed (corresponding to a state indicated by a black round dot in FIG. 11 A) and hence, in step S5, the increment d is added to a capacity deterioration rate D at a point of time of the previous calculation.

In a case where the value obtained by adding the intercept b to the initial capacity increase rate E is less than zero in step S4 (S4: No), it is determined in step S6 whether or not a value obtained by adding the intercept b and the increment d to the initial capacity increase rate E is zero or more. When this value is zero or more (S6: Yes), the state is just a timing that a period during which the characteristics of the energy storage device are maintained or enhanced has just elapsed (corresponding to a state indicated by a black round dot in FIG. 11B) and hence, in step S7, the initial capacity increase rate E, the intercept b and the increment d are added to the capacity deterioration rate D at the point of time of the previous calculation. In addition,-b that is obtained by multiplying the intercept b (minus value) by a minus is substituted to the initial capacity increase rate E.

In step S6, when the value obtained by adding the intercept b and the increment d to the initial capacity increase rate E is less than zero (S6: No), the value is within the period in which the characteristics of the energy storage device are maintained or enhanced (corresponding to a state indicated by a black round dot in FIG. 11C). Accordingly, in step S8, the increment d is added to the initial capacity increase rate E at the point of time of the previous calculation.

By sequentially calculating the capacity deterioration rate by the method illustrated in FIG. 10, the accuracy of the deterioration estimation can be enhanced even when the range SOC or the temperature changes during the operation of the energy storage device.

The present invention is not limited to the above-described embodiment, and can be appropriately changed.

The estimation method and the computer program may be performed by the client device 3 in place of the server device 2 illustrated in FIG. 1, or may be performed by the communication device 1 or the management device M illustrated in FIG. 2.

1. An estimation device for estimating deterioration of an energy storage device, wherein
the estimation device is configured such that, during an initial period of an operation of the energy storage device in which characteristics are maintained or enhanced, a deterioration value that indicates the deterioration is not substantially increased.

2. The estimation device according to claim 1, wherein a determination relating to an increase in the deterioration value is made based on a magnitude of a fluctuation in a state of charge (SOC) during the initial period of the operation of the energy storage device.

3. The estimation device according to claim 2, wherein as the magnitude of the fluctuation in the SOC is larger, a full charge capacity of the energy storage device during the initial period of the operation is more largely increased, and the deterioration value of the energy storage device having the increased full charge capacity is increased.

4. The estimation device according to claim 2, wherein when the SOC of the energy storage device fluctuates up to a predetermined number of cycles with a first magnitude, and then the SOC of the energy storage device fluctuates with a second magnitude that is larger than the first magnitude, a full charge capacity of the energy storage device during the initial period of the operation is increased based on the second magnitude, and the deterioration value of the energy storage device having the increased full charge capacity is increased.

5. The estimation device according to claim 1, wherein a determination relating to an increase in the deterioration value is made based on a temperature during the initial period of the operation of the energy storage device.

6. An estimation method of estimating deterioration of an energy storage device, the estimation method comprising:
not substantially increasing a deterioration value that indicates the deterioration during an initial period of an operation of the energy storage device in which characteristics are maintained or enhanced.

7. A computer program allowing a computer that estimates deterioration of an energy storage device to perform processing of
not substantially increasing a deterioration value that indicates the deterioration during an initial period of an operation of the energy storage device in which characteristics are maintained or enhanced.
